(19) United States
(12) Patent Application Publication
(10) Pub. No.: US 2012/0100721 A1
(43) Pub. Date: Apr. 26, 2012

(54) METHOD FOR TREATING A SEMICONDUCTOR WAFER

(75) Inventor: Kaidong Xu, Villach (AT)

(73) Assignee: LAM RESEARCH AG, VILLACH (AT)

(21) Appl. No.: 13/380,322

(22) PCT Filed: Jun. 14, 2010
(86) PCT No.: PCT/IB2010/052646

§ 371 Date: Dec. 22, 2011

(30) Foreign Application Priority Data
Jun. 25, 2009 (AT) A989/2009

(51) Int. Cl. H01L 21/306

(52) U.S. Cl. 438/704; 257/E21.215

(57) ABSTRACT

A method for treating semiconductor wafer includes: providing a stack including a high-k layer including a first oxide material, wherein the first oxide material contains hafnium and/or zirconium, and a cap-layer including a second oxide material, wherein the cap-layer has been deposited on top of the high-k layer, wherein the second oxide material contains lanthanum, a lanthanide and/or aluminium; supplying liquid A to the surface of the semiconductor wafer, liquid A being an aqueous solution containing an oxidizing agent; supplying liquid B to the surface of the semiconductor wafer, liquid B being a liquid with a pH-value lower than 6; and conducting a step SC wherein a liquid C is supplied to the surface of the semiconductor wafer, wherein step SC is carried out after step SB, wherein liquid C is an aqueous acidic solution with a fluorine concentration of at least 10 ppm.

### TECHNICAL FIELD

The invention refers to a method for treating a semiconductor wafer.

More specifically it refers to a method for wet treatment of a semiconductor wafer.

### BACKGROUND ART

FIG. 1 shows a schematic cross-sectional view of an example of a high-k metal gate stack 1 before a method according to an embodiment of the invention is applied. On the bulk silicon 10 of a silicon wafer a number of layers are deposited in this order:

TABLE 1

| reference | | | |
|---|---|---|---|
| number | material | thickness | |
| 20 | hafnium oxide as high-k material | 1-5 | nm |
| 30 | lanthanum oxide as cap-layer | 0.2-2 | nm |
| 40 | Titanium nitride as metal-layer | 2-50 | nm |
| 50 | polycrystalline silicon as silicon layer | 20-100 | nm |
| 60 | silicon nitride as hard mask | 60 | nm |

Before depositing the high-k material an interfacial layer (not shown) is deposited at a thickness of up to 1 nm. Such an interfacial layer can be silicon oxide or silicon oxynitride.

Alternatively to the hafnium oxide 20 other materials with a dielectric constant of greater than 10 can be deposited. Suitable materials are e.g. hafnium silicates, zirconium oxides, hafnium silicon oxy nitrides, zirconium silicates, hafnium aluminates, zirconium aluminates, or combinations thereof.

Alternatively to the lanthanum oxide 30 other cap layer materials can be used such as aluminium oxide, a lanthanide oxide (such as dysprosium oxide), or combinations thereof.

Alternatively to the titanium nitride as a metal layer other titanium-based or tantalum-based materials or other materials can be used.

Alternatively to the polycrystalline silicon other silicon layers can be used such as amorphous silicon.

Alternatively to the silicon nitride as a hard mask silicon oxide can be used.

Examples for such stacks are described in S. Kubicek et al, IEDM Tech. Dig., p. 49, 2007 and A. Toriumi et al, IEDM Tech. Dig., p. 53, 2007.

A photolithography step is carried out to expose the stack where the stack layers shall be removed in order to expose the bulk silicon. The to-be-removed areas are treated with a plasma process. In the to-be-removed areas (where no photo-resist is present) the silicon nitride layer 60, the polycrystalline silicon layer 50 and the titanium nitride layer 40 are generally removed. The lanthanum oxide layer 30 and the high-k layer 20 are modified by the plasma treatment so that modified lanthanum oxide 25 and modified high-k material 35 is generated (see FIG. 1). During the plasma treatment residues are generated. The carbon-rich residues 75 (deriving from photo resist) remain on top of the hard mask 60. Sidewall residues remain on the sidewall of the etched stack, which are basically metal-enriched residues 45 adhering on the sidewall and silicon-enriched residues 55 adhering on the metal-enriched residues.

It is an object of the invention to remove the residues, and to remove the cap-layer as well as the high-k layer, on which no metal layer 40 or silicon layer 50 remains, and leave a clean structure without undercut of high-k or metal layers.

### DISCLOSURE OF INVENTION

The invention solves the problems by providing a method for treating semiconductor wafer comprising:
providing a stack comprising:
   a high-k layer comprising a first oxide material, wherein the first oxide material contains hafnium and/or zirconium, and
   a cap-layer comprising a second oxide material, wherein the cap-layer has been deposited on top of the high-k layer, wherein the second oxide material contains lanthanum, a lanthanide and/or aluminium,
conducting a step SA wherein a liquid A is supplied to the surface of the semiconductor wafer, wherein liquid A is an aqueous solution,
conducting a step SB wherein a liquid B is supplied to the surface of the semiconductor wafer, wherein step SB is carried out after (e.g. subsequent) step SA, wherein liquid B is a liquid with a pH-value lower than 6, and
conducting a step SC wherein a liquid C is supplied to the surface of the semiconductor wafer, wherein step SC is carried out after (e.g. subsequent) step SB.

Typically the stack has been deposited on the surface of a bare silicon wafer, wherein the surface has been doped for providing specific regions of an integrated circuit. The stack is used as a so-called high-k metal gate structure.

Preferably the first oxide consists of zirconium oxide, hafnium oxide, hafnium silicate, zirconium silicate, hafnium aluminate, zirconium aluminate, or combinations thereof.

Preferably the cap-layer consists of lanthanum oxide, aluminium oxide, a lanthanide oxide (e.g. dysprosium oxide), or a combination thereof.

On top of the cap-layer the following layers may be deposited in the following order: Metal-layer (e.g. titanium nitride), polycrystalline silicon, and a hard mask (e.g. silicon nitride) on top.

Without being bound to any theory the following is assumed:

Step SA helps removing post dry etch residues such as sidewall polymers e.g. silicon rich residues and metal rich residues and carbon-rich residues (e.g. deriving from photo-resist) on top of the stack.

Step SB helps removing the cap-layer in the open area thereby however avoiding the under-cut etching of the cap-layer.

Step SC helps removing the high-k material in the open area thereby however avoiding the under-cut etching of either the cap-layer or the high-k material.

It shall be mentioned that between each step an intermediate rinsing step can be carried out. Such intermediate rinsing step is preferred between step SA and SB.

In a preferred embodiment a method liquid A is selected from the group consisting of the following aqueous solutions:

a) an aqueous solution containing oxidizing agent at an analytical concentration of 0.001-10 mol/l (preferably 0.01-1 mol/l), and having a pH-value lower than 6.5 (preferably lower than 6) or higher than 7.5 (preferably higher than 8). Preferred oxidizing agents are hydrogen peroxide or ozone dispersed and/or dissolved in water.

b) an aqueous solution containing ammonia at an analytical concentration of 0.005-0.5 mol/l (preferably in the range of 0.01-0.1 mol/l), and hydrogen peroxide at an analytical concentration of 0.001-10 mol/l (preferably in the range of 0.01-1 mol/l), wherein the molar ration of ammonia and hydrogen peroxide is in the range of 1:10 to 10:1. Such solutions are known as e.g. dSC1, which is diluted aqueous solution of ammonia and hydrogen peroxide.

c) an aqueous solution containing sulphuric acid at an analytical concentration of 0.001-10 mol/l, and hydrogen peroxide (as oxidizing agent) at an analytical concentration of 0.001-10 mol/l (sub 0.01-1 mol/l), wherein the molar ration of sulphuric acid and hydrogen peroxide is in the range of 1:10 to 10:1 (e.g. dSP, a diluted mixture of sulphuric acid and hydrogen peroxide);

d) an aqueous solution containing sulphuric acid at an analytical concentration of 0.001-10 mol/l, and ozone (as oxidizing agent) at a concentration of >1 ppm (preferably greater than 10 ppm) (e.g. dSOM, a diluted sulphuric acid to which ozone is added). Such a solution is known dSOM, a diluted sulphuric acid to which ozone is added;

e) an aqueous solution containing hydrochloric acid at an analytical concentration of 0.001-10 mol/l, and hydrogen peroxide (as oxidizing agent) at an analytical concentration of 0.001-10 mol/l (sub 0.01-1 mol/l), wherein the molar ration of sulphuric acid and hydrogen peroxide is in the range of 1:10 to 10:1. Such a solution is known as dSC2, a diluted solution of hydrochloric acid and hydrogen peroxide.

Preferably liquid A is an aqueous solution containing ammonia at an analytical concentration of 0.005-0.5 mol/l, and hydrogen peroxide (as oxidizing agent) at an analytical concentration of 0.001-10 mol/l (preferably 0.01-1 mol/l), wherein the molar ration of ammonia and hydrogen peroxide is in the range of 1:10 to 10:1 (e.g. dSC1).

In another embodiment liquid B is an aqueous liquid with a pH-value in a range 6 and 0 (preferably in the range of 5.5 and 2), with an analytical concentration of oxidizing agents of below 10 ppm. Preferably the concentration of fluorine in liquid B shall be below 1 ppm.

Advantageously the liquid B is an aqueous solution containing hydrochloric acid at an analytical concentration of lower than 3.7 wt.-% (lower than 1.2 mol/l)

In yet another embodiment liquid C is a liquid with a pH-value lower than 6.5 and a fluorine concentration of greater than 10 ppm (preferably in a range of 10 ppm-5%).

Preferably the liquid C is contains hydrochloric acid and hydrofluoric acid.

In an embodiment in step SC liquid C is supplied at a temperature greater than 25° C. (preferably greater than 30° C.), which further supports the selective removal of the high-k material in the exposed (open) area.

Advantageously after step SC a step SD is conducted wherein a liquid D is supplied, wherein liquid D is a liquid with a pH-value lower than 6. Here the same kind of liquid can be used as in step SB. This step SD further helps to remove residues.

Preferably liquid D is an aqueous liquid with a pH-value in a range 6.5 and 0 (preferably in the range of 5.5 and 2), with a concentration of oxidizing agents of below 10 ppm.

In another embodiment the stack further comprises
a metal-layer (e.g. TiN; TaN; Ta₂C) on top of the cap-layer,
a layer of polycrystalline silicon on top of the metal-layer, and
a hard-mask (e.g. Si₃N₄; SiO₂ on Si₃N₄) on top of the polycrystalline silicon.

Using such a method in combination with such a stack is helpful because it removes residues, which are generated during dryetching of hard-mask, polycrystalline silicon and metal-layer and furthermore removing exposed cap-layer and high-k-layer and thus leaving a clean structure in a short process.

This is the case especially if prior to step SA a dry etching step is conducted wherein the stack is patterned by removing the stack on specific areas, where according to a previous photo lithography step no photo-resist was present.

Preferably all steps (SA, SB, SC) are conducted as single wafer processing steps, which significantly shortens the over all process time and avoids any kind of recontamination.

### BRIEF DESCRIPTION OF DRAWINGS

FIG. 1 shows schematic cross-sectional view of a high-k metal gate stack before a method according to an embodiment of the invention is applied.

FIG. 2 shows schematic cross-sectional view of a high-k metal gate stack after a method according to an embodiment of the invention has been applied.

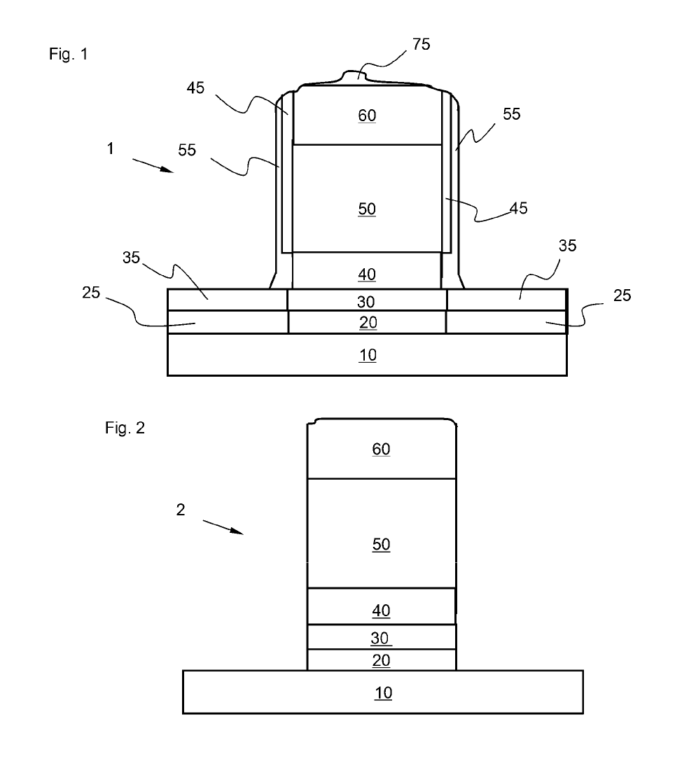

### MODE(S) FOR CARRYING OUT THE INVENTION

Preferred methods are carried out as follows:

### Example 1

Starting with the stack as above-described in section “Background Art” the wet treatment method is carried out by means of a spin processor where liquid is poured onto the rotating wafer.
Step SA: liquid A, which is an aqueous solution of ammonia (c_{HCl}=2 g/l) and hydrogen peroxide (c_{NH3}=3 g/l), is supplied at 25° C. for 30 s at 300 rpm
Rinsing step: deionised water is supplied for 20 s at 25° C. while the wafer is rotated at 300 rpm
Step SB: liquid B, which is an aqueous solution of hydrogen chloride (c_{HCl}=2 g/l), is supplied at 25° C. for 30 s at 300 rpm
Step SC: liquid C, which is an aqueous solution of hydrofluoric acid (c_{HF}=1 g/l) and hydrochloric acid (c_{HCl}=40 g/l), is supplied at 40° C. for 30 s at 300 rpm
Rinsing step: deionised water is supplied for 20 s at 25° C. while the wafer is rotated at 300 rpm
Step SD: liquid D, which is an aqueous solution of hydrogen chloride (c_{HCl}=2 g/l), is supplied at 25° C. for 30 s at 300 rpm
Final rinsing step: deionised water is supplied for 20 s at 25° C. while the wafer is rotated at 300 rpm
Drying with N₂, which is blown onto the substrate.

After this process not only the modified layers (modified cap-layer 35, modified high-k layer) are removed but also the stack structure is cleaned from all residues as shown in FIG. 2.

### Example 2

This method according to example 2 is based on example 1 wherein the step SA is changed in that the components of liquid A have a higher concentration (ammonia (c_{HCl}=4 g/l) and hydrogen peroxide (C_{NH3}=6 g/l)) and the liquid A is supplied for only 15 s.

### Example 3

This method according to example 3 is based on example 1, wherein the step SB is changed in that as liquid B a different solution is selected. Liquid B is an aqueous solution of sulphuric acid (c_{H2SO4}=20 g/l).

All three examples 1, 2 and 3 lead to surfaces with clean gate structures without any significant undercut of any of the metal layer, cap-layer and high-k layer.

### Comparative Example

1^{st} step: a first liquid, which is an aqueous solution of ammonia (c_{HCl}=2 g/l) and hydrogen peroxide (C_{NH3}=3 g/l), is supplied at 25° C. for 30 s at 300 rpm.
Rinsing step: deionised water is supplied for 20 s at a 25° C. while the wafer is rotated at 300 rpm.
2^{nd} step: a second liquid, which is an aqueous solution of hydrofluoric acid (c_{HF}=1 g/l) and hydrochloric acid (c_{HCl}=40 g/l), is supplied at 40° C. for 30 s at 300 rpm.
Final rinsing step: deionised water is supplied for 20 s at a 25° C. while the wafer is rotated at 300 rpm.
Drying with N₂, which is blown onto the substrate.

When a wafer is treated with a method according to the comparative example residues are left on the structured wafer surface. A problem is that such residues protect the modified cap layer from being etched so that cap-layer and/or high-k material is removed on some areas, whereas they are not removed on most areas. Such structure can then hardly be recovered or is finally destructed.

An intermediate rinsing step (between the 1^{st} step and the 2^{nd} step) supplying a diluted acidic acid however leads to a satisfactory result.

1. A method for treating semiconductor wafer comprising:
providing a stack comprising:
a high-k layer comprising a first oxide material, wherein the first oxide material contains hafnium and/or zirconium, and
a cap-layer comprising a second oxide material, wherein the cap-layer has been deposited on top of the high-k layer, wherein the second oxide material contains lanthanum, a lanthanide and/or aluminium,
conducting a step SA wherein a liquid A is supplied to the surface of the semiconductor wafer, wherein liquid A is an aqueous solution containing an oxidizing agent,
conducting a step SB wherein a liquid B is supplied to the surface of the semiconductor wafer, wherein step SB is carried out after step SA, wherein liquid B is a liquid with a pH-value lower than 6, and
conducting a step SC wherein a liquid C is supplied to the surface of the semiconductor wafer, wherein step SC is carried out after step SB, wherein liquid C is an aqueous acidic solution with a fluorine concentration of at least 10 ppm.

2. Method according claim 1 wherein liquid A is selected from the group consisting of:
an aqueous solution containing an oxidizing agent at an analytical concentration of 0.001-10 mol/l, and having a pH-value lower than 6.5 or higher than 7.5;
an aqueous solution containing ammonia at an analytical concentration of 0.005-0.5 mol/l, and hydrogen peroxide as oxidizing agent at an analytical concentration of 0.001-10 mol/l, wherein the molar ration of ammonia and hydrogen peroxide is in the range of 1:10 to 10:1;
an aqueous solution containing sulphuric acid at an analytical concentration of 0.001-10 mol/l, and hydrogen peroxide as oxidizing agent at an analytical concentration of 0.001-10 mol/l, wherein the molar ration of sulphuric acid and hydrogen peroxide is in the range of 1:10 to 10:1
an aqueous solution containing sulphuric acid at an analytical concentration of 0.001-10 mol/l, and ozone as oxidizing agent at a concentration of >1 ppm
an aqueous solution containing hydrochloric acid at an analytical concentration of 0.001-10 mol/l, and hydrogen peroxide as oxidizing agent at an analytical concentration of 0.001-10 mol/l, wherein the molar ration of sulphuric acid and hydrogen peroxide is in the range of 1:10 to 10:1

3. Method according to claim 2 wherein liquid A is an aqueous solution containing ammonia at an analytical concentration of 0.005-0.5 mol/l, and hydrogen peroxide at an analytical concentration of 0.001-10 mol/l, wherein the molar ration of ammonia and hydrogen peroxide is in the range of 1:10 to 10:1.

4. Method according to claim 1 wherein the liquid B is an aqueous liquid with a pH-value in a range 6 and 0, with an analytical concentration of oxidizing agents of below 10 ppm.

5. Method according to claim 4 wherein the liquid B is an aqueous solution containing hydrochloric acid at an analytical concentration of below 3.7 wt.-%.

6. Method according to claim 4 wherein the liquid B has a fluorine concentration of below 1 ppm.

7. Method according to claim 1 wherein the liquid C is a liquid with a pH-value lower than 6.5 and a fluorine concentration of greater than 10 ppm.

8. Method according to claim 7 wherein the liquid C contains hydrochloric acid and hydrofluoric acid.

9. Method according to claim 1 wherein in step SC liquid C is supplied at a temperature greater than 25° C.

10. Method according to claim 9 wherein in step SC liquid C is supplied at a temperature greater than 30° C.

11. Method according to claim 1 wherein after step SC a step SD is conducted wherein a liquid D is supplied, wherein liquid D is a liquid with a pH-value lower than 6.

12. Method according to claim 11 wherein liquid D is an aqueous liquid with a pH-value in a range 6.5 and 0, with a concentration of oxidizing agents of below 10 ppm.

13. Method according to claim 1 wherein the stack further comprises
a metal-layer (e.g. TiN; TaN; Ta₂C) on top of the cap-layer,
a layer of polycrystalline silicon on top of the metal-layer, and
a hard-mask (e.g. Si₃N₄; SiO₂ on Si₃N₄) on top of the polycrystalline silicon.

14. Method according to claim 1 wherein prior to step SA a dry etching step is conducted wherein the stack is patterned by removing the stack on specific areas, where according to a previous photo lithography step no photo-resist was present.

15. Method according to claim 1 wherein all steps (SA, SB, SC) are conducted as single wafer processing steps.
